(19) United States
(12) Patent Application Publication
(10) Pub. No.: US 2026/0287628 A1
(43) Pub. Date: Sep. 24, 2026

(54) Detection circuit and detection method

(71) Applicant: NOVATEK Microelectronics Corp., Hsin-Chu (TW)

(72) Inventors: Chia-Wei Wang, Hsinchu City (TW); Cheng-Chun Wu, New Taipei City (TW); Yen-Wei Chen, Hsinchu City (TW)

(73) Assignee: NOVATEK Microelectronics Corp., Hsin-Chu (TW)

(21) Appl. No.: 19/221,542

(22) Filed: May 29, 2025

(30) Foreign Application Priority Data
Mar. 18, 2025 (TW) 114110026

(51) Int. Cl. G01R 27/20

(52) U.S. Cl. CPC G01R 27/205

(57) ABSTRACT

A detection circuit includes an input circuit and a sensing circuit. The input circuit includes a first input node and a second input node. The first input node is coupled to a first detection node and the second input node is coupled to a second detection node. The sensing circuit includes a current source providing a predetermined current. The current source is coupled to the first input node. The sensing circuit generates a sensing voltage at an output node in response to the predetermined current. The first detection node directly contacts the second detection node or is electrically connected to the second detection node through a trace, and the sensing voltage is related to an impedance between the first detection node and the second detection node.

### BACKGROUND OF THE INVENTION

### 1. Field of the Invention

The invention relates to a detection circuit of a panel device, more particular to a detection circuit capable of accurately detecting characteristic parameters of electronic components in the panel device.

### 2. Description of the prior Art

With the rapid advancement of technology, display panels are commonly equipped with touch sensing and control functions, making them extensively applied to numerous electronic products such as smartphones, tablet PCs, and laptops. In recent years, the application of display panels has been further extended to automotive display systems.

However, the performance requirements for the display panels in electronic products varies in different scenarios. For instance, unlike the high-resolution requirement for devices like smartphones or computers, when display panels are used in automotive display systems, their primary consideration is ensuring normal operation during vehicle operation. This is because the accurate display of driving-related information and the control of the vehicle are critical for driving safety.

Therefore, preventing abnormalities in the display and touch functions of display panels has become a significant challenge in the field of automotive displays.

### SUMMARY OF THE INVENTION

According to an embodiment of the invention, a detection circuit comprises an input circuit and a sensing circuit. The input circuit comprises a first input node and a second input node. The first input node is coupled to a first detection node and the second input node is coupled to a second detection node. The sensing circuit comprises a current source providing a predetermined current. The current source is coupled to the first input node. The sensing circuit generates a sensing voltage at an output node in response to the predetermined current. The first detection node directly contacts the second detection node or is electrically connected to the second detection node through a trace, and the sensing voltage is related to an impedance between the first detection node and the second detection node.

According to an embodiment of the invention, a detection method, for detecting an impedance between two nodes by using a detection circuit, comprises: coupling a first detection node to a first input node of the detection circuit, and coupling a second detection node to a second input node of the detection circuit, wherein the first detection node directly contacts the second detection node or is electrically connected to the second detection node through a trace; controlling a current source of the detection circuit to provide a first current; receiving a first sensing voltage from an output node of the detection circuit in response to the first current; controlling the current source of the detection circuit to provide a second current; receiving a second sensing voltage from the output node of the detection circuit in response to the second current; and determining a value of the impedance between the first detection node and the second detection node according to a difference between the second sensing voltage and the first sensing voltage.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a schematic diagram showing an example of incomplete contact of the conductive layers distributed on the surfaces where the driver chip and the panel glass are contacted due to thermal expansion and contraction effects.

FIG. 2 is another schematic diagram showing an example of incomplete contact of the conductive layers distributed on the surfaces where the driver chip and the panel glass are contacted with each other due to product deformation which is caused by pressure.

FIG. 3 shows an exemplary block diagram of the detection circuit according to an embodiment of the invention.

FIG. 4 shows an exemplary circuit diagram of a detection circuit according to an embodiment of the invention.

FIG. 5 shows an exemplary circuit diagram of a detection circuit according to an embodiment of the invention.

FIG. 6 shows several exemplary nodes providing the ground voltage in a display system.

FIG. 7 shows an example of setting up a detection circuit in a display system to perform the current, voltage, or impedance detection according to an embodiment of the invention.

FIG. 8 shows another example of setting up a detection circuit in a display system to perform the current, voltage, or impedance detection according to an embodiment of the invention.

FIG. 9 shows a flowchart of a detection method according to an embodiment of the invention.

FIG. 10 shows an example of displaying the error code according to an embodiment of the invention.

### DETAILED DESCRIPTION

As mentioned above, display panels have become basic equipment in today's vehicles. In vehicle display systems, display panels are used to display important driving-related information, such as vehicle speed, mileage, tire pressure, navigation maps, etc., and can also be used to provide control interfaces for in-vehicle equipment, such as controlling audio volume, controlling air conditioning temperature, etc.

Typically, the display panel is driven by a driver chip, and the driver chip may be installed on the panel glass through the bonding or press technology (for simplification, the term “bonding” will be used in the following paragraphs). However, the conductive layers of the driver chip and the panel glass may encounter problems of poor contact or incomplete contact due to product aging or thermal expansion and contraction effects, causing the bonding impedance (also known as pressing impedance), which theoretically should have a zero value, to increase and become to have a non-zero value, such as having a non-zero resistance. In this disclosure, bonding impedance or pressing impedance refers to the impedance between two nodes or two layers (e.g., metal layers or conductive layers) that are directly connected or directly contact, or electrically connected through bonding technology.

FIG. 1 is a schematic diagram showing an example of incomplete contact of the conductive layers distributed on the surfaces where the driver chip and the panel glass are contacted due to thermal expansion and contraction effects. As shown in FIG. 1, the driver chip 100 is installed on the display panel 150 through bonding technology, and the driver chip 100 and the display panel 150 may be electrically connected through multiple connection nodes, for example, through the nodes 102, 104, 106, and 108 of the driver chip 100 and the nodes 152, 154, 156, and 158 of the display panel 150.

The nodes 102, 104, 106, and 108, as well as the nodes 152, 154, 156, and 158, may respectively be pins or pads of the driver chip 100 and the display panel 150. Or, they may respectively be metal layers or conductive layers of the driver chip 100 and the display panel 150, or the nodes comprised in or configured on the metal surfaces or metal balls of the driver chip 100 and the display panel 150. Ideally, the node 102 completely contacts the node 152, the node 104 completely contacts the node 154, the node 106 completely contacts the node 156, and the node 108 completely contacts the node 158. Here, the “completely contact” means that the conductive parts of the two nodes are in perfect contact with each other so as to achieve an optimal electrical connection (e.g., minimum impedance therebetween). For example, the conductive parts of the two nodes completely contact with each other or completely overlap.

However, due to thermal expansion and contraction effects, the driver chip 100 or the display panel 150 begins to deform, leading to incomplete contact of the nodes. For example, the nodes 108 and 158 may be displaced due to product deformation, causing the contact or overlapped area between them to significantly decrease, resulting in a weakly connected condition.

Since the electrical connection between the nodes 108 and 158 is not completely broken, the transmission of electrical signals through the nodes 108 and 158 will not be immediately interrupted, making this weakly connected condition difficult to be detected. However, as the product keeps being used, once the deformation of the driver chip 100 or the display panel 150 worsens, the electrical connection between the nodes 108 and 158 may break at any time, by then, obvious errors that can be observed by the user may occur.

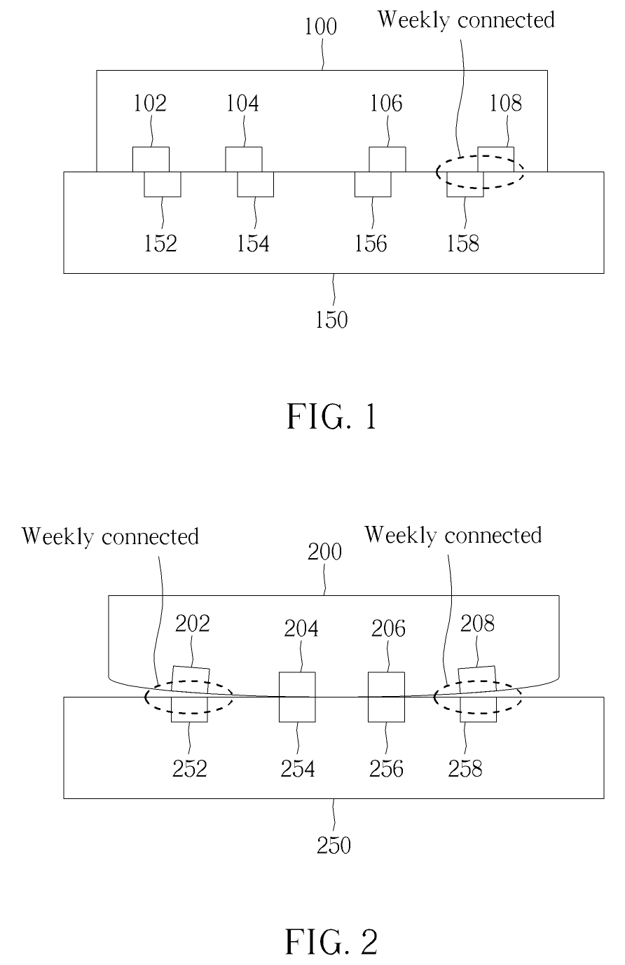

FIG. 2 is another schematic diagram showing an example of incomplete contact of the conductive layers distributed on the surfaces where the driver chip and the panel glass are contacted with each other due to product deformation which is caused by pressure. As shown in FIG. 2, the driver chip 200 is installed on the display panel 250 through bonding technology, and the driver chip 200 and the display panel 250 may be electrically connected through multiple connection nodes, for example, through the nodes 202, 204, 206, and 208 of the driver chip 200 and the nodes 252, 254, 256, and 258 of the display panel 250.

Similarly, the nodes 202, 204, 206, and 208, as well as the nodes 252, 254, 256, and 258, may respectively be pins or pads of the driver chip 200 and the display panel 250. Or, they may respectively be metal layers or conductive layers of the driver chip 200 and the display panel 250, or the nodes comprised in or configured on the metal surfaces or metal balls of the driver chip 200 and the display panel 250. Ideally, the node 202 completely contacts the node 252, the node 204 completely contacts the node 254, the node 206 completely contacts the node 256, and the node 208 completely contacts the node 258.

However, the driver chip 200 may deform due to external pressure, leading to incomplete contact of the nodes, for example, the nodes 202 and 252, as well as the nodes 208 and 258, may completely or partially separate due to product deformation, causing the contact or overlapped area between the two nodes to significantly decrease, resulting in a weakly connected condition.

Since the weakly connected condition may affect the display function or touch sensitivity of the panel, thereby endangering driving safety, accurate detection of the electronic characteristic parameters associated with the vehicle panel is very important. In this disclosure, a detection circuit and associated detection method capable of accurately detecting characteristic parameters of electronic components in the vehicle panel are proposed. By applying the proposed detection circuit and associated detection method, the weakly connected or incomplete contact condition in the display device can be detected at an early stage. In other words, whether the bounding between the display chip (e.g., the driver chip) and the panel is incomplete can be detected, or the bounding condition can keep being monitored by the proposed detection circuit detect. Once the incompleteness of the bounding between the display chip and the panel or the poor bounding condition is detected, the user will be notified for subsequent maintenance. For example, the proposed detection circuit is also capable of determining the bonding condition of the circuits through a lookup table of circuit bonding conditions versus detected resistance values.

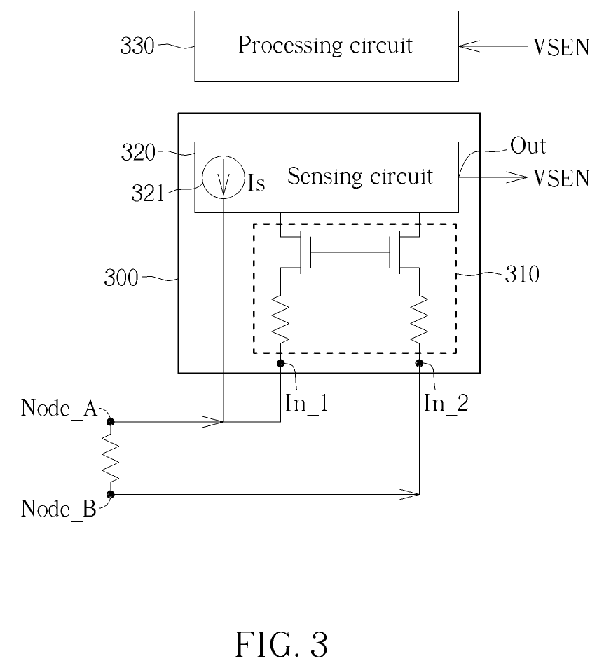

FIG. 3 shows an exemplary block diagram of the detection circuit according to an embodiment of the invention. The detection circuit 300 may comprise an input circuit 310 and a sensing circuit 320. The input circuit 310 comprises input nodes In_1 and In_2. The sensing circuit 320 comprises at least a current source 321 providing a predetermined current Is. The current source 321 is coupled to the input node In_1, and the sensing circuit 320 generates a sensing voltage VSEN at the output node Out in response to the predetermined current Is.

The detection circuit 300 detects the impedance between two nodes. According to an embodiment of the invention, the input node In_1 of the detection circuit 300 is coupled to the detection node Node_A, the input node In_2 is coupled to the detection node Node_B, and the sensing voltage VSEN generated by the detection circuit 300 is related to the impedance between the detection nodes Node_A and Node_B. That is, the sensing voltage VSEN generated by the detection circuit 300 may be utilized to determine or derive the value of the impedance between the detection nodes Node_A and Node_B.

According to an embodiment of the invention, the detection nodes Node_A and Node_B are two nodes that should have equal potentials, theoretically. More specifically, the detection nodes Node_A and Node_B may be two nodes that directly contact or are electrically connected through a trace. For example, the detection nodes Node_A and Node_B may be two nodes electrically connected through a bonding wire, or two nodes directly contact through bonding or pressing technology.

According to an embodiment of the invention, the detection nodes Node_A and Node_B are nodes of different devices or two different nodes of the same device. For example, the detection node Node_A may be a node inside the driving chip of the display panel (e.g., any node of the driving chip as shown in FIGS. 1 or 2), and the detection node Node_B may be a node of the display panel (e.g., the node on the display panel and corresponding to the aforementioned node of the driving chip as shown in FIGS. 1 or 2). Alternatively, the detection nodes Node_A and Node_B may be two nodes on the driving chip, display panel, Printed Circuit Board (PCB), or Flexible Printed Circuit (FPC).

Since the detection nodes Node_A and Node_B are directly contacted or electrically connected, the two nodes theoretically should have equal potentials, so the impedance between the detection nodes Node_A and Node_B should theoretically be zero. However, in practice, due to product aging, thermal expansion and contraction effects, external pressure, or any other factors, the detection nodes Node_A and Node_B may have poor contact or incomplete contact, resulting in a small impedance exists therebetween.

In general, it is not easy to accurately detect a small impedance between two nodes. The detection circuit must be capable of achieving extremely high precision in detection to make the detection results meaningful. In addition, when the voltage of the node equals the ground voltage, it further increases the difficulty of detection. For example, in existing technology, the detection of a ground voltage requires the additional use of a negative voltage or the use of multiple power sources with different voltage levels, thus increasing the cost and complexity of the detection circuit. The proposed detection circuit overcomes these difficulties and implements accurate detection of electronic characteristic parameters at low cost. In addition, the proposed detection circuit is capable of precisely detecting changes in zero-ohm impedance.

According to an embodiment of the invention, the detection circuit 300 comprises a plurality of transistors, and the detection circuit 300 uses the source electrode of the transistors as an input. For example, the detection nodes Node_A and Node_B shown in FIG. 3 may be respectively coupled to the source electrode of the transistors through the input nodes In_1 and In_2, so as to detect changes in zero-ohm impedance or zero-volt voltage , or changes in the impedance close to zero-ohm or in the impedance between the nodes having a voltage difference close to zero-volt (e.g., tiny bonding impedance). The detection circuit 300 can also reversely perform current detection, which overcomes the dilemma in existing technology where it is difficult to detect small impedance or ground voltage using low-cost circuits.

According to an embodiment of the invention, the processing circuit 330 may be coupled to the sensing circuit 320 and detect the impedance according to the sensing voltage VSEN. It should be noted that in some embodiments, the processing circuit 330 may be independent of the detection circuit 300, while in other embodiments, the processing circuit 330 may be comprised in the detection circuit 300. For example, in some embodiments, multiple sets of detection circuits may be configured in the system to detect the impedance between multiple pairs of nodes. The processing circuit may be coupled to these detection circuits to control the operation of these detection circuits and detect or derive the impedance between each pair of nodes. More detailed introductions will be provided in the following paragraphs.

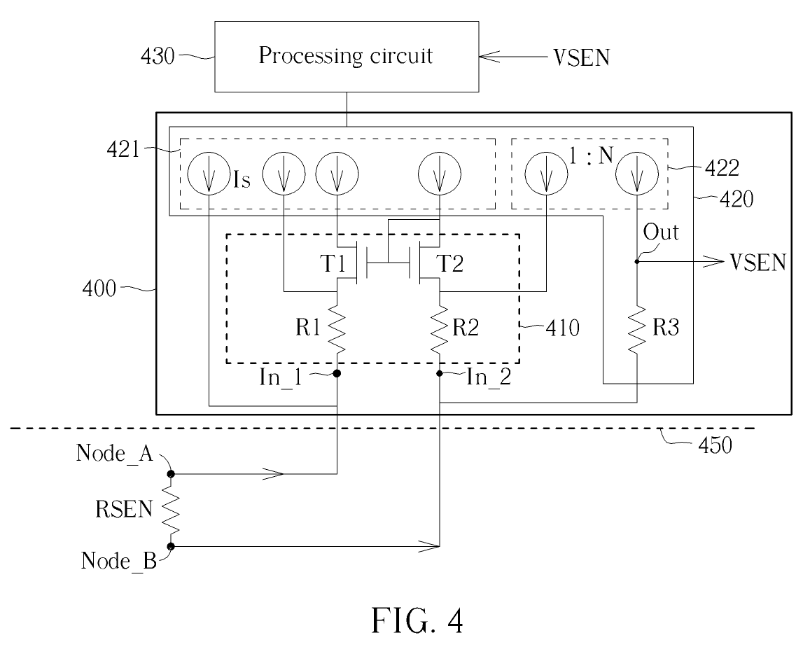

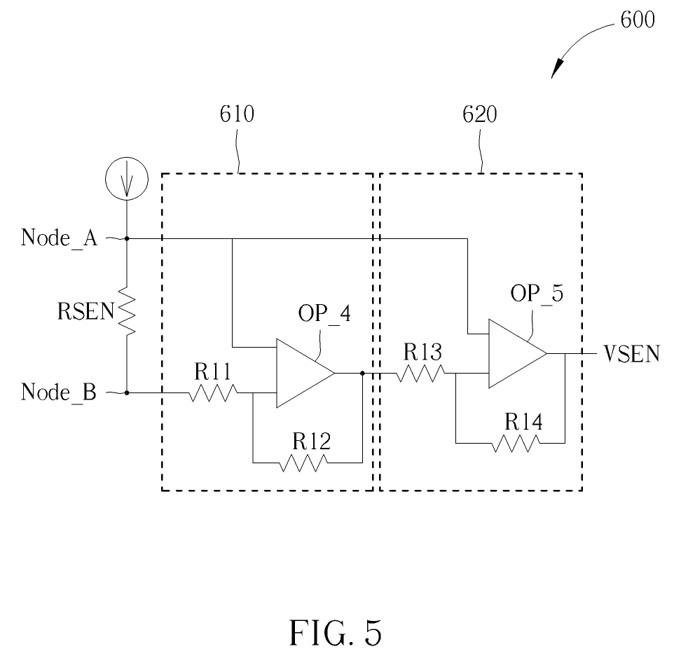

FIG. 4 shows an exemplary circuit diagram of a detection circuit according to an embodiment of the invention. The detection circuit 400 comprises an input circuit 410 and a sensing circuit 420.

In this example, the object to be measured is the value of the impedance between the detection nodes Node_A and Node_B, represented by the resistor RSEN in FIG. 4. The input node In_1 of the detection circuit 400 is coupled to the detection node Node_A and the input node In_2 is coupled to the detection node Node_B, for detecting the value of the impedance between the detection nodes Node_A and Node_B.

The input circuit 410 comprises transistors T1 and T2. The source electrode of transistor T1 may be coupled to the input node In_1, for example, the source electrode of transistor T1 is coupled to the input node In_1 through resistor R1. The source electrode of transistor T2 may be coupled to the input node In_2, for example, the source electrode of transistor T2 is coupled to the input node In_2 through resistor R2.

The sensing circuit 420 comprises a current source module 421 and a current mirror circuit 422. The current source module 421 may comprise multiple current sources, for example, a current source for providing a predetermined current Is, and one or more current sources for providing current to the source electrode, drain electrode, or gate electrode of transistors T1 and T2. The current mirror circuit 422 may produce a current flowing through the output node Out according to a predetermined ratio, for example, 1:N, where N is a positive number. The sensing circuit 420 may generate a sensing voltage VSEN at the output node Out in response to the current (e.g., at least comprising the predetermined current Is) generated by the current sources in the current source module 421. The output node Out may be coupled to the detection node Node_B through resistor R3.

As described above, detection nodes Node_A and Node_B may be nodes of different devices, or two different nodes of the same device. For example, detection node Node_A may be a node in the driver chip of a display panel, and detection node Node_B may be a node corresponding to the aforementioned node of the driving chip on the display panel. For another example, detection nodes Node_A and Node_B may be two nodes on a driver chip, display panel, PCB, or FPC.

The sensing voltage VSEN generated by the detection circuit 400 is related to the impedance between the detection nodes Node_A and Node_B. That is, the sensing voltage VSEN generated by the detection circuit 400 may be used to determine or derive the impedance between the detection nodes Node_A and Node_B.

According to an embodiment of the invention, the detection nodes Node_A and Node_B are two nodes that theoretically should have equal potential. More specifically, the detection nodes Node_A and Node_B may be two nodes that are in direct contact or electrically connected through a trace. For example, the detection nodes Node_A and Node_B may be respectively comprised in two different devices and electrically connected through a bonding wire. For another example, the detection nodes Node_A and Node_B may be respectively comprised in two different metal surfaces, and the two metal surfaces are in direct contact, for example, in direct contact through bonding technology.

In addition, according to an embodiment of the invention, the detection nodes Node_A and Node_B are respectively coupled to a system voltage, for example, a system voltage of a display system. In one embodiment, the detection nodes Node_A and Node_B are both coupled to a power supply voltage VDD. In another embodiment, the detection nodes Node_A and Node_B are both coupled to a ground voltage GND.

According to an embodiment of the invention, the detection circuit 400 is implemented in a driver chip, for example, the detection circuit 400 may be a built-in circuit to perform Built-In Self-Test (BIST) in the driver chip of the display panel.

A division line 450 drawn in FIG. 4 is utilized to distinguish between the driver chip part and the non-driver chip part. The circuit above the division line 450 is within the driver chip, and the circuit below the division line 450 may be the circuit comprised in the display panel, PCB, or FPC. It should be noted that the division line 450 in FIG. 4 is only illustrative, and the actual circuit does not contain this line.

In an embodiment of the invention, the detection circuit 400 implemented in the driver chip may be utilized to detect the value of the impedance between any two nodes on the driver chip, display panel, PCB, or FPC.

According to an embodiment of the invention, the processing circuit 430 may be coupled to the sensing circuit 420 and detect the impedance according to the sensing voltage VSEN. It should be noted that, as described above, in some embodiments, the processing circuit 430 may be independent of the detection circuit 400, while in other embodiments, the processing circuit 430 may be comprised in the detection circuit 400, and the invention is not limited to any specific implementation.

According to an embodiment of the invention, the processing circuit 430 controls the amount of the predetermined current Is to be switched from a first amount to a second amount. In response to the first amount of the predetermined current, the processing circuit 430 receives a first sensing voltage VSEN1 from the output node Out, and in response to the second amount of the predetermined current, the processing circuit 430 receives a second sensing voltage VSEN2 from the output node Out. The processing circuit 430 may determine or derive the value of the impedance between the detection nodes Node_A and Node_B according to the difference between the second sensing voltage VSEN2 and the first sensing voltage VSEN1.

According to an embodiment of the invention, in addition to being related to the impedance value between the detection nodes Node_A and Node_B, the sensing voltage VSEN is also related to the value of the predetermined ratio N of the current mirror circuit, the predetermined current Is, and the values of the resistance or impedance of resistors R1 and R2, where the value N, the amount of current Is, and the values of the resistance or impedance of resistors R1 and R2 are known design parameters. Additionally, the sensing voltage VSEN also comprises voltage components generated by non-ideal effects.

The processing circuit 430 obtains the difference of the sensing voltage to eliminate the voltage components generated by non-ideal effects and retain the voltage components related to the known design parameters. Therefore, the resulting difference is related to the value N, the amount of current Is, and the values of the resistance or impedance of resistors RSEN, R1, and R2, and the processing circuit 430 may derive the value of resistance or impedance of resistor RSEN based on the resulting difference.

According to an embodiment of the invention, the first amount of the predetermined current may be set to 0 amp, so the resulting sensing voltage may be utilizing for calibrating the non-ideal effects. The second amount of the predetermined current may be set to another value greater than 0 amp. In an embodiment of the invention, the processing circuit 430 first controls or sets the amount of the predetermined current Is to 0, and obtains the corresponding first sensing voltage VSEN1, then controls or sets the amount of the predetermined current Is to another value, and obtains the corresponding second sensing voltage VSEN2. The processing circuit 430 derives the value of resistance or impedance of the resistor RSEN based on the difference between the second sensing voltage VSEN2 and the first sensing voltage VSEN1.

Through the structure of the detection circuit and control of the detection flow as introduced above, a low complexity (e.g., only requiring a few current sources) and low power consumption current, voltage, or impedance detection is achieved, and the detection accuracy is up to very small changes in zero-ohm impedance or zero-volt voltage , or changes in the impedance close to zero-ohm or in the impedance between the nodes having a voltage difference close to zero-volt (e.g., tiny bonding impedance).

According to an embodiment of the invention, the processing circuit 430 further determines whether the impedance value of resistor RSEN is abnormal. For example, the processing circuit 430 may determine whether the impedance value is abnormal based on a threshold value. An abnormal value of the impedance may reflect that two nodes that theoretically should have equal potential no longer have equal potential, or reflect that the voltage level or current magnitude of the nodes has become abnormal, for example, having deviated from the ideal or predetermined value. In response to a determination result indicating that the impedance value is abnormal, the processing circuit 430 may generate an error code or a warning message, and may control the display of the error code or warning message on the display panel. Additionally, the processing circuit 430 may store the abnormal information in a memory device inside the chip as reference information for service personnel, which will help locate where the abnormality occurred and improve repair efficiency.

FIG. 5 shows an exemplary circuit diagram of a detection circuit according to an embodiment of the invention. In this embodiment, the detection circuit 600 comprises operational amplifiers OP_4 and OP_5 and multiple resistors R11, R12, R13, and R14, forming an input circuit 610 and a sensing circuit 620. In this embodiment, the source electrode or gate electrode of a transistor (e.g., a transistor comprised in the operational amplifier OP_4) is utilized as the input of the detection circuit 600. For instance, the detection nodes Node_A and Node_B may be respectively coupled to the source electrode or gate electrode of the transistor, and the object to be detected is the resistor RSEN between the detection nodes Node_A and Node_B. The detection circuit 600 may detect changes in zero-ohm impedance or zero-volt voltage, or changes in the impedance close to zero-ohm or in the impedance between the nodes having a voltage difference close to zero-volt (e.g., tiny bonding impedance) through the resulting sensing voltage VSEN. The detection circuit 600 may also perform reverse current detection, achieving low complexity, low power consumption, and high precision current, voltage, or impedance detection.

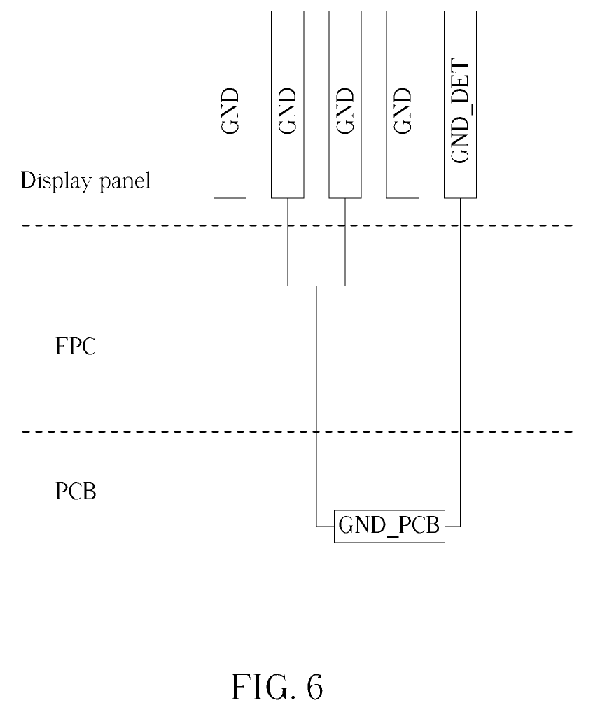

FIG. 6 shows several exemplary nodes providing the ground voltage in a display system. In this example, the ground voltage nodes GND providing ground voltage on the display panel are all electrically connected to the corresponding ground voltage node GND_PCB on the PCB through traces or bonding wires, and may be further electrically connected to the ground voltage detection node GND_DET on the display panel through a trace or bonding wire. Alternatively, the ground voltage nodes GND on the display panel may be all electrically connected to the ground voltage detection node GND_DET on the display panel through a trace or bonding wire via an FPC and a PCB (i.e., in another example, there is no ground voltage node GND_PCB on the PCB, and the ground voltage nodes GND on the display panel are directly in contact or connected to the ground voltage detection node GND_DET through only traces or bonding wires on the FPC and the PCB).

To detect whether the ground voltage provided by each node is correct, or to detect the value of the impedance between multiple nodes providing the ground voltage, any one of the ground voltage node GND, the ground voltage detection node GND_DET, or the ground voltage node GND_PCB on the PCB may be the detection node Node_A in this disclosure, and another one of them may be the detection node Node_B in this disclosure, and the associated current, voltage, or impedance detection may be performed by using the proposed detection circuit.

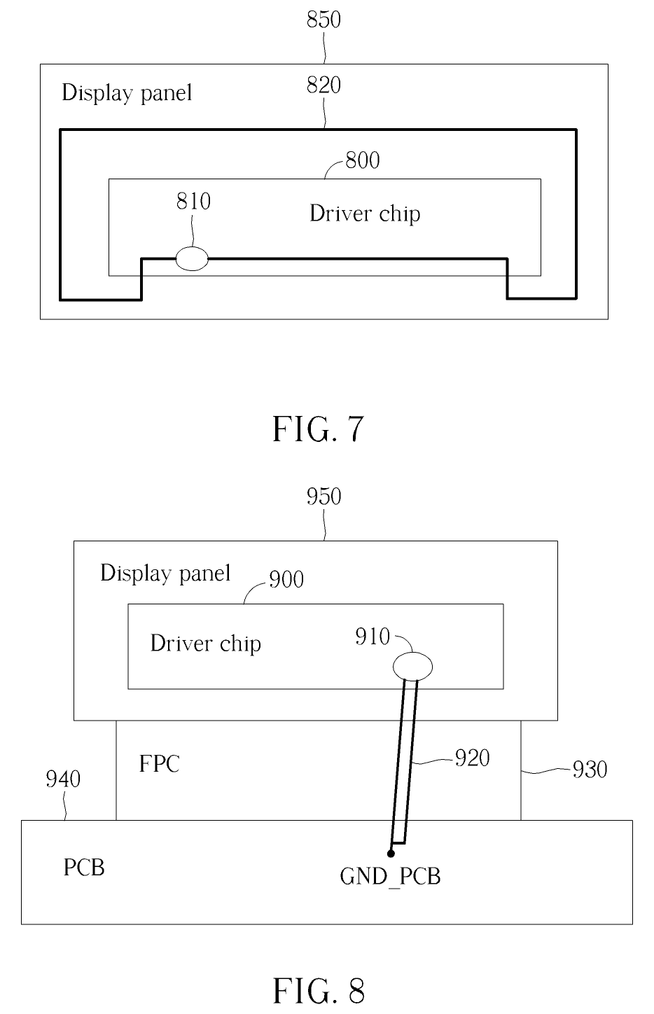

FIG. 7 shows an example of setting up a detection circuit in a display system to perform the current, voltage, or impedance detection according to an embodiment of the invention. The driver chip 800 in the display system is installed on the display panel 850 through bonding technology, and the driver chip 800 and the display panel 850 may be electrically connected through multiple connection points. A portion of the trace 820 is the wiring within the driver chip 800, and the other portion is the wiring within the display panel 850. In this example, the detection circuit 810 may be coupled to any two nodes on the trace 820 (therefore, the detection circuit 810 is not limited to be arranged only at the position shown in FIG. 7), and the detection circuit 810 may be used to detect the bonding impedance between the driver chip 800 and the display panel 850. If the value of the bonding impedance between the driver chip 800 and the display panel 850 is not zero-ohm, it may reflect that bonded conductive layers on the surfaces where the driver chip 800 and the display panel 850 are contacted have an incomplete contact.

FIG. 8 shows another example of setting up a detection circuit in a display system to perform the current, voltage, or impedance detection according to an embodiment of the invention. The driver chip 900 in the display system is installed on the display panel 950 through bonding technology, and the driver chip 900 and the display panel 950 may be electrically connected through multiple connection points. The driver chip 900 may be electrically connected to the ground voltage node GND_PCB on the PCB 940 through the trace 920. The trace 920 may be routed from the PCB 940 back to the driver chip 900, so the trace 920 may comprise wirings within the driver chip 900, the display panel 950, the FPC 930, and the PCB 940.

In this example, the detection circuit 910 may be coupled to any two nodes on the trace 920 (therefore, the detection circuit 910 is not limited to being arranged only at the position shown in FIG. 8), and the detection circuit 910 may be arranged to detect the ground voltage. Therefore, the detection circuit 910 may detect whether the ground voltage has become abnormal throughout the entire path of the trace 920. For example, determining whether two nodes are incompletely contacted by detecting the value of the impedance between the two nodes. If the value of the impedance is not zero-ohm, it may reflect that there is an incomplete contact between two nodes that are supposed to have equal voltage levels.

It should be noted that in other embodiments, the ground voltage node GND_PCB shown in FIG. 8 may be replaced with a node coupled to a power supply voltage, so the detection circuit 910 may be used to detect abnormalities in the power supply voltage (e.g., VDD).

In addition, in the embodiments of the invention, the static current inside the driver chip may also be calculated from the obtained value of the impedance, and whether the static current has become abnormal may be further determined, to avoid excessive current causing the ground potential inside the driver chip to rise and resulting in the failure of the driver chip's function.

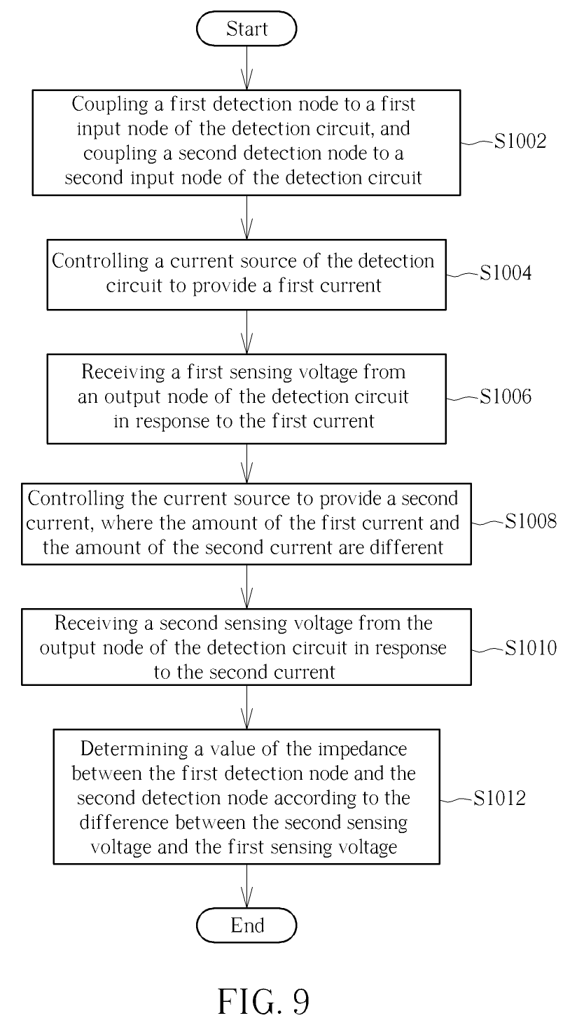

FIG. 9 shows a flowchart of a detection method according to an embodiment of the invention, comprising the following steps:

Step S1002: Coupling a first detection node to a first input node of the detection circuit, and coupling a second detection node to a second input node of the detection circuit. According to an embodiment of the invention, the first detection node directly contacts the second detection node or is electrically connected to the second detection node through a trace, or the first detection node and the second detection node are two nodes that theoretically or by product design should have equal potential.

Step S1004: Controlling a current source of the detection circuit to provide a first current.

Step S1006: Receiving a first sensing voltage from an output node of the detection circuit in response to the first current.

Step S1008: Controlling the current source to provide a second current, where the amount of the first current and the amount of the second current are different.

Step S1010: Receiving a second sensing voltage from the output node of the detection circuit in response to the second current.

Step S1012: Determining a value of the impedance between the first detection node and the second detection node according to the difference between the second sensing voltage and the first sensing voltage.

As described above, the value of the impedance obtained in step S1012 may be utilized to determine whether the voltage level or current magnitude of the detection nodes has become abnormal. In response to a determination result indicating that the voltage, current, or impedance has become abnormal, the processing circuit may generate an error code or a warning message, and may control the display of the error code or warning message on the display panel. In an embodiment of the invention, the abnormal detection performed by the detection circuit may be combined with on-screen display (OSD) to remind the user of the occurrence of an abnormal state through OSD.

It should be noted that, taking automotive display systems as an example, OSD may be used to display or notify the user of abnormalities or errors in the vehicle system, which are abnormalities or errors related to the vehicle itself or driving. For example, abnormal tire pressure, abnormal temperature, etc. In an embodiment of the invention, in addition to displaying existing vehicle system errors, OSD may further display or notify the user of electronic characteristic abnormalities in the display panel, driver chip, or automotive display system, that is, the voltage, current, or impedance abnormalities detected by the aforementioned detection circuit. Therefore, by implementing the proposed detection circuit and detection method, the OSD of the automotive display system may not only display abnormalities or errors in the vehicle itself, but also display abnormalities or errors within the display system.

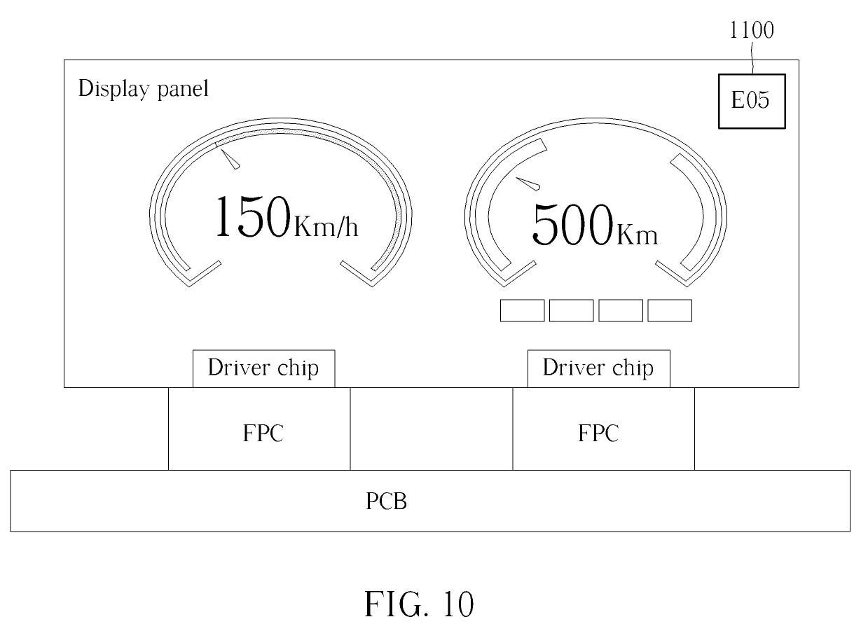

FIG. 10 shows an example of displaying the error code according to an embodiment of the invention. As shown in FIG. 10, when the processing circuit determines that the voltage, current, or impedance has become abnormal, it may display an error code (e.g., the error code “E05” shown in FIG. 10) in the display area 1100 of the display panel, for reminding the user to arrange vehicle inspection and repair early to ensure driving safety. Additionally, the processing circuit may store the abnormal information in a memory device inside the chip as a reference information for service personnel, which will help locate where the abnormality occurred and improve repair efficiency.

In summary, the proposed detection circuit achieves precise detection of zero-ohm impedance changes with a low-cost and low-complexity circuit, which is not only capable of detecting changes in zero-ohm impedance or zero-volt voltage , or changes in the impedance close to zero-ohm or in the impedance between the nodes having a voltage difference close to zero-volt (e.g., tiny bonding impedance), but also capable of reversely performing current detection, which overcomes the dilemma in existing technology where it is difficult to detect small impedance or ground voltage using low-cost circuits.

In addition, because the proposed detection circuit is low-cost and low-complexity, it is applicable for performing multi-point detection. For example, multiple sets of detection circuits may be configured in the display system and respectively used to detect impedance values between different pairs of nodes, making the detection more complete and improving product safety.

In addition, since the weakly connected condition between devices or nodes, as well as the current, voltage, or impedance abnormalities, actually all carry potential risks, by implementing the proposed detection circuit, abnormal states with potential risks in the system may be detected, making the product's safety protection more complete, which benefits to improve the product's Automotive Safety Integrity Level (ASIL).

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A detection circuit, comprising:
an input circuit, comprising a first input node and a second input node, wherein the first input node is coupled to a first detection node and the second input node is coupled to a second detection node; and
a sensing circuit, comprising a current source providing a predetermined current, wherein the current source is coupled to the first input node, and the sensing circuit generates a sensing voltage at an output node in response to the predetermined current, and
wherein the first detection node directly contacts the second detection node or is electrically connected to the second detection node through a trace, and the sensing voltage is related to an impedance between the first detection node and the second detection node.

2. The detection circuit of claim 1, further comprising:
a processing circuit, coupled to the sensing circuit and detecting a value of the impedance according to the sensing voltage,
wherein the processing circuit controls an amount of the predetermined current to be switched from a first amount to a second amount,
the processing circuit receives a first sensing voltage from the output node in response to the first amount of the predetermined current and receives a second sensing voltage from the output node in response to the second amount of the predetermined current, and
the processing circuit further determines the value of the impedance according to a difference between the second sensing voltage and the first sensing voltage.

3. The detection circuit of claim 1, wherein the first detection node and the second detection node are respectively coupled to a system voltage of a display system.

4. The detection circuit of claim 3, wherein the system voltage is a power supply voltage or a ground voltage.

5. The detection circuit of claim 1, wherein the input circuit further comprises:
a first transistor, comprising a source electrode coupled to the first input node; and
a second transistor, comprising a source electrode coupled to the second input node.

6. The detection circuit of claim 1, wherein the first detection node is comprised in a first device, the second detection node is comprised in a second device, and the first detection node is electrically connected to the second detection node through a bonding wire.

7. The detection circuit of claim 1, wherein the first detection node is comprised in a first metal surface of a first device, the second detection node is comprised in a second metal surface of a second device, and the first metal surface directly contacts the second metal surface.

8. The detection circuit of claim 2, wherein the processing circuit further determines whether the value of the impedance is abnormal according to a threshold value, and in response to a determination result indicating that the value of the impedance is abnormal, the processing circuit generates an error code or a warning message.

9. A detection method, for detecting an impedance between two nodes by using a detection circuit, comprising:
coupling a first detection node to a first input node of the detection circuit, and coupling a second detection node to a second input node of the detection circuit, wherein the first detection node directly contacts the second detection node or is electrically connected to the second detection node through a trace;
controlling a current source of the detection circuit to provide a first current;
receiving a first sensing voltage from an output node of the detection circuit in response to the first current;
controlling the current source of the detection circuit to provide a second current;
receiving a second sensing voltage from the output node of the detection circuit in response to the second current; and
determining a value of the impedance between the first detection node and the second detection node according to a difference between the second sensing voltage and the first sensing voltage.

10. The detection method of claim 9, wherein the first detection node and the second detection node are respectively coupled to a system voltage of a display system.

11. The detection method of claim 10, wherein the system voltage is a power supply voltage or a ground voltage.

12. The detection method of claim 9, wherein the first detection node is coupled to a source electrode of a first transistor of the detection circuit through the first input node, and the second detection node is coupled to a source electrode of a second transistor of the detection circuit through the second input node.

13. The detection method of claim 9, wherein the first detection node is comprised in a first device, the second detection node is comprised in a second device, and the first detection node is electrically connected to the second detection node through a bonding wire.

14. The detection method of claim 9, wherein the first detection node is comprised in a first metal surface of a first device, the second detection node is comprised in a second metal surface of a second device, and the first metal surface directly contacts the second metal surface.

15. The detection method of claim 9, further comprising:
determining whether the value of the impedance is abnormal according to a threshold value; and
generating an error code or a warning message to be displayed by a display panel in response to a determination result indicating that the value of the impedance is abnormal.
